(19) United States
(12) Patent Application Publication
(10) Pub. No.: US 2015/0219565 A1
(43) Pub. Date: Aug. 6, 2015

(54) APPLICATION OF IN-LINE THICKNESS METROLOGY AND CHAMBER MATCHING IN DISPLAY MANUFACTURING

(71) Applicant: Applied Materials, Inc., Santa Clara, CA (US)

(72) Inventors: Ilias ILIOPOULOS, Foster City, CA (US); Shuo NA, Sunnyvale, CA (US); Kelby YANCY, Forney, TX (US); Chunsheng CHEN, Tianjin (CN)

(21) Appl. No.: 14/610,367

(22) Filed: Jan. 30, 2015

Related U.S. Application Data
(60) Provisional application No. 61/935,758, filed on Feb. 4, 2014.

(51) Int. Cl. G01N 21/84; G01B 11/06; C23C 16/52

(52) U.S. Cl. CPC G01N 21/8422; C23C 16/52; G01B 11/0625; G01N 2201/12

(57) ABSTRACT

A method and apparatus for measuring the thickness of a deposited layer are disclosed herein. Devices as described herein can include a transfer chamber, one or more processing chambers each having an entrance, a loadlock chamber comprising a loadlock entrance and a loadlock exit; and an optical monitoring system comprising a plurality of optical devices positioned proximate to at least one of the entrances. Methods as described herein can include delivering a substrate with at least one deposited layer through an opening in a chamber, activating an optical monitoring system at the opening of the chamber such that the optical monitoring system performs a plurality of optical measurements of the deposited layers, delivering the optical measurements to a signal processing system and correlating the optical measurements to one or more film attributes.

### CROSS-REFERENCE TO RELATED APPLICATIONS

This application claims priority to U.S. Provisional Patent Application Ser. No. 61/935,758, filed on Feb. 4, 2014, which is incorporated by reference herein.

### BACKGROUND

1. Field

Embodiments disclosed herein generally relate to a optical monitoring device for use with processed substrates and methods of use. More specifically, embodiments generally relate to uniformity and thickness control in thin film deposition.

2. Description of the Related Art

Substrates must be scanned for defects both before any patterning is done and after patterning to identify sites with defects that would lead to a bad device. As substrates become larger and pattern features become smaller, the problem of scanning becomes more difficult. Methods or strategies for improved scanning for defects thus become increasingly important in keeping the cost of inspection in line with the cost of patterning the wafers in the first place. In addition, rapid scanning of wafers and similar devices is important for extended production runs to avoid an accumulation of defective substrates upon entrance to the chamber or defective processed substrates due to processing issues.

Film thickness uniformity of the deposited layers, such as an amorphous silicon (a-Si) active layer, has large impact on TFT-LCD device performance. Recent high mobility active layer materials, such as low-temperature polycrystalline silicon (LTPS) and metal oxides, require even tighter thickness uniformity control. The thickness uniformity requirements for more advanced LTPS displays have been tightened to from about 3% to about 5%.

Attempts to monitor thickness in deposited films have met with limited success. Display panel manufacturers have employed off-line ellipsometers to sample thickness for one substrate out of a batch of 20 or more. However, such post-deposition analysis inherently comes too late for prevention or detection of excursions. Customers have long desired on-the-fly thickness measurement capability for every substrate and the ability to make recipe/hardware adjustments quickly in case of process drift or an excursion event. However, measurement speed and tool integration capable of providing real-time thickness measurement has remained elusive.

Therefore, there is a need for improved devices and methods for measuring film thickness and uniformity.

### SUMMARY

Embodiments disclosed herein generally relate to methods and devices for measuring the film attributes of a deposited layer. In one embodiment, a processing device is provided. The processing chamber can include a transfer chamber, one or more processing chambers, a loadlock chamber and an optical monitoring system. The processing chambers can each include a processing entrance proximate the transfer chamber. The loadlock chamber can include a loadlock entrance and a loadlock exit. The optical monitoring system can be positioned outside of and under an opening. The opening selected from the processing entrance, the loadlock entrance or the loadlock exit. The optical monitoring system can include a plurality of optical devices positioned horizontally under the opening. The optical monitoring system can further include a radiation source, a radiation detector, a substrate detector, and a signal processing system, where the optical monitoring system is configured to deliver radiation at a substrate position.

In another embodiment, a method of measuring film attributes is provided. The method can begin by delivering a substrate through an opening in a processing chamber, the substrate having at least one deposited layer disposed on a surface of the substrate, the opening in the processing chamber having an optical monitoring system positioned in connection therewith. Then, the optical monitoring system can be activated, such that the optical monitoring system performs a plurality of optical measurements of the at least one deposited layer, where the optical measurements are continuous along the respective region of the substrate. The optical measurements can then be delivered to a signal processing system. Finally, the optical measurements can be correlated to one or more film attributes.

In another embodiment, a method of measuring film attributes is provided. The method can include positioning a substrate in a processing chamber, the substrate having a first surface and a second surface opposite the first surface. One or more silicon-containing layers can then be deposited on the first surface of the substrate. The substrate can then be transferred to a second chamber, the second chamber having an optical monitoring system. Radiation can then be emitted from the optical monitoring system toward a plurality of points on the second surface, the silicon-containing layer receiving and reflecting a portion of the radiation creating reflected radiation. The reflected radiation can then be received and interpreted as optical measurements corresponding to the plurality of points. The optical measurements can then be delivered to a signal processing system. Finally, the optical measurements can be correlated to one or more film attributes, where the film attributes include a film thickness, a film composition and a film uniformity of each of the one or more silicon-containing layers.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A shows a top plan view of an substrate processing system suitable for depositing silicon-containing layers on a substrate, according to one embodiment;

FIG. 1B depicts the substrate during the measuring process, measured according to one embodiment;

FIG. 2 is a block diagram of a method for measuring film attributes, according to one embodiment; and

FIGS. 3A, 3B and 3C depict graphs of thickness maps of a plurality of silicon-containing layers, measured according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate apparatus and methods for monitoring and controlling a large area substrate processing system. The concept of the invention can be applied to substrates greater than 750 cm², such as substrates greater than 2000 cm², substrates greater than 15000 cm², or substrates greater than 40000 cm². The present methods and devices provide solutions for immediate tool thickness profile fingerprint monitor and thickness and/or uniformity excursion control in device manufacture, such as the TFT array side films in display manufacturing. Film stacks can include but are not limited to amorphous silicon (a-Si), silicon nitride (SiNx) and silicon oxide (SiOx) layers, which are part of a group referred to generically as silicon-containing layers. These layers can be deposited using Applied Materials AKT deposition tools among other deposition tools. The developed in-line metrology tools and methods have substantially no impact on throughput and robot movement. The thickness and uniformity data collected can then be sent to a database to be used in fault detection and tool interdiction applications.

The silicon-containing layers can be processed in high volume and high throughput by different types of process chambers, for example, physical vapor deposition (PVD) and sputtering chambers, ion metal implant (IMP) chambers, chemical vapor deposition (CVD) chambers, atomic layer deposition (ALD) chambers, plasma etching chambers, annealing chambers, other furnace chambers, cleaning stations, etc. The substrate processing system may include a deposition chamber in which a substrate is exposed to one or more gas-phase materials or plasma. In one embodiment, the substrate processing system is also configured to include various types of process chambers to perform, for example, different etching, deposition, annealing, and cleaning processes.

For systems with PVD and/or CVD processing chambers, the performance or condition of the PVD and/or CVD processing chambers can be monitored and controlled by using metrology tools to collect post-processing film information, such as film thickness, film composition, film uniformity, and the like, after substrate processing. The measurement information can be used to detect a fault in the system, which may cause the measured data to suddenly fall outside a pre-determined control range or the measured data trend differs from the normal data trend. Once the fault is detected, the system can be set up to prevent further substrate processing until the source(s) of fault is identified or corrected. The embodiments disclosed herein are more clearly described with reference to the figures below.

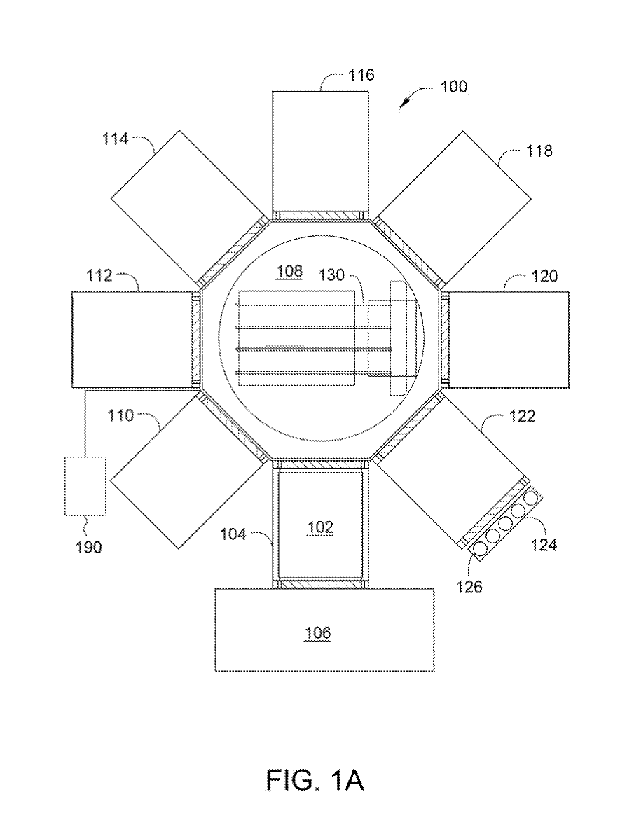

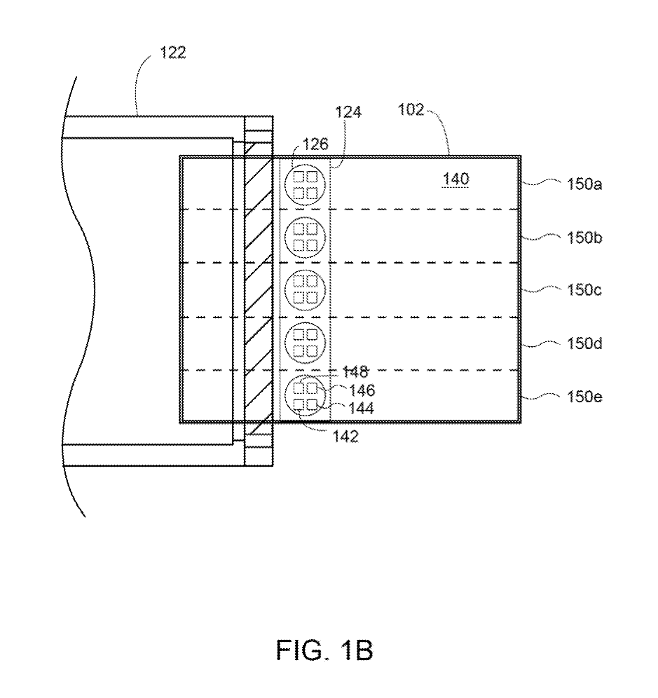

The measurement can be performed in-situ, which occurs in the processing chamber, or ex-situ, which occurs outside the processing chamber. In one embodiment, a cluster type substrate processing system 100, as shown in FIG. 1, including a plurality of process chambers, for example chambers 110, 112, 114, 116, 118 and 120, at least one of which is a chemical vapor deposition (CVD) configured to deposit a silicon-containing layer on a substrate, for example chamber 110. In another embodiment, the substrate processing system is also configured to include other types of process chambers, for example chambers 112, 114, 116, 118 and 120, configured to perform additional etching, deposition, annealing, and cleaning processes.

FIG. 1A shows a top plan view of an exemplary substrate processing system 100 suitable for depositing silicon-containing layers on a substrate 102. The substrate processing system 100 typically includes a transfer chamber 108 coupled to a factory interface 106 via a loadlock chamber 104. The factory interface 106 generally includes one or more substrates stored therein or substrate storage cassettes. The substrate storage cassettes are typically removably disposed in a plurality of storage bays/compartments formed inside the factory interface 106. The factory interface 106 may also include an atmospheric robot, such as a dual blade atmospheric robot. The atmospheric robot is adapted to transfer one or more substrates between the one or more substrate storage cassettes and the loadlock chamber 104. Typically, the factory interface 106 is maintained at or slightly above atmospheric pressure and the loadlock chamber 104 is disposed to facilitate substrate transfer between a vacuum environment of the transfer chamber 108 and a generally ambient environment of the factory interface 106. The substrate 102 processed by the substrate processing systems can be transferred from the factory interface 106 to the loadlock chamber 104 for processing of a fabrication sequence including two or more metal layer depositions on one or more substrates 102 without the substrate 102 leaving the system 100. Transfer robot 130 can transfer substrates between transfer chamber 108, process chambers 110, 112, 114, 116, 118 and 120, and a metrology chamber 122. The metrology chamber 122 may be a loadlock chamber or a chamber designed for a metrology process. The process chambers 110, 112, 114, 116, 118 and 120 can be a PECVD chamber available from AKT America, Inc., a subsidiary of Applied Materials, Inc., located in Santa Clara, Calif. It is to be understood that the invention has applicability in other chambers as well, including apparatus available from other manufacturers.

Shown here, an optical monitoring system 124 is positioned at the exit of the metrology chamber 122. The optical monitoring system 124 is depicted as having a plurality of optical devices 126. The number of optical devices in the plurality of optical devices 126, shown here as five, is limited only by the available space to position the optical devices 126 on the optical monitoring system 124. In one embodiment, the plurality of optical devices 126 includes fourteen (14) optical devices. The optical monitoring system 124 is positioned such that the plurality of optical devices 126 are facing the bottom of the substrate 102 (opposite the silicon-containing layer).

The optical monitoring system 124 is capable of measuring critical dimensions (CDs), film thickness, film uniformity and other film attributes of the deposited layer in-situ (during plasma processing) and/or ex-situ (before or after plasma processing). The optical monitoring system 124 may use one or more non-destructive optical measuring techniques, such as spectroscopy, interferometry, scatterometry, reflectometry, and the like. In one embodiment, the optical monitoring system uses reflectometry. The optical monitoring system 124 may be, for example, configured to perform an interferometric monitoring technique (e.g., counting interference fringes in the time domain, measuring position of the fringes in the frequency domain, and the like) to measure the etch depth profile of the structure being formed on the substrate 102 in real time. In another embodiment, the wavelength of radiation produced or delivered from the optical monitoring system 124 will penetrate through the substrate and at least a portion of the radiation delivered will be received back from the silicon-containing layer. Travel time for the radiation, the wavelength used and other radiation parameters can be used to differentiate between different types of silicon-containing layers.

The measurement can be done upon entrance to or exit from one or more of the transfer chamber 108, the loadlock 102, the process chambers, 110, 112, 114, 116, 118 and 120, or metrology chamber 122. For systems for processing large area substrates, the transfer chamber 108, the loadlock 102, the process chambers, 110, 112, 114, 116, 118 and 120, and metrology chamber 122 are all sized to accommodate large area substrates. Each of the transfer chamber 108, the loadlock 102, the process chambers, 110, 112, 114, 116, 118 and 120, and separate metrology chamber 122 can include multiple metrology tools to collect pre-processing and post-processing data on the substrates.

For process control purposes, a user can measure film attributes, such as film thickness and film uniformity, after deposition in the process chamber. If the measured data fall out of the control range, the system can receive a control signal to suspend further substrate processing until the cause of process drift is identified. For example, the substrate 102 is placed in a process chamber 110 to deposit a first silicon-containing layer. After the layer deposition, the post-deposition layer properties of the substrate 102 can be measured by metrology tools located at the entrance/exit of the process chamber 110, the transfer chamber 108, a metrology chamber 122, or loadlock 102. In one embodiment, after a silicon-containing layer is deposited on the substrate 102, the substrate 102 is delivered through the metrology chamber 122 to measure at least one post-deposition property. The post deposition film attributes include, but are not limited to, properties such as film thickness, film content, film uniformity, sheet resistance, particle count, and film stress. After the film attribute has been measured, the substrate 102 can be placed in another chamber 112 to deposit a second silicon-containing layer. After the second layer deposition, at least one of the post-deposition film attributes of the second layer on the substrate 102 can be measured by metrology tools placed at the entrance/exit of process chamber 112, the transfer chamber 108, a metrology chamber 122, or loadlock 102. The post-deposition measurement can be performed on both layers to monitor and control both chambers. The post-deposition measurement can be performed on only one layer to monitor and control only one chamber. When more than one process chamber is used, it is possible that only one chamber is selected to be monitored and controlled. Typically, the chamber that deposits a film whose film attribute is more critical, such as uniformity of a very thin film, is selected to be monitored. The substrate processing system 100 is controlled by a system control unit 190, which could include controller(s), computer(s), and memory (or memories).

FIG. 1B depicts the substrate 102 measured according to one embodiment. In this embodiment, the substrate 102 has one or more silicon-containing layers 140. The one or more silicon containing layers 140 can be composed of amorphous silicon (a-Si), polycrystalline silicon, silicon nitride (SiNx), silicon oxide (SiOx) or combinations thereof. The substrate 102 is then delivered through the metrology chamber 122 and over the optical monitoring system 124.

Each optical device 126 can include component structures, such as a radiation source 142, a radiation detector 144, a substrate presence detector 146 and a signal processing system 148. Though each optical device 126 is shown with four component structures, the optical devices 126 can function with less than all four. Further, certain component structures can be shared between optical devices 126 or stored at a location remote from the optical devices 126.

Each optical device of the optical monitoring system 124 measures one or more of the film attributes of the silicon-containing layer 140 in the regions which are visible to the optical device, depicted here as regions 150a-150e. Though the regions 150a-150e are depicted as non-overlapping, the regions 150a-150e may overlap. Further, though depicted here as five regions 150a-150e, the number of regions will depend on the number of optical devices in use. In some embodiments, the regions will not completely cover the surface area of the substrate 102. Thus, the optical monitoring system 124 here would measure less than the entirety of the silicon-containing layer 140. In this case, the optical monitoring system 124 can anticipate the measured film attribute based on nearby measurements.

In this embodiment, the measurements of the film attributes are taken during standard movement of the substrate from the metrology chamber 122. In one embodiment, the substrate is moving at a speed of 0.2-2.0 meters per second. As the substrate 102 passes over the optical monitoring system 124, the optical monitoring system 124 is alerted to the presence of the substrate 102 by a signal received from the substrate presence detector 146. In response to the signal received, the radiation source 142 delivers radiation to the silicon-containing layer 140 on the substrate 102. Information on the film attributes of the silicon-containing layer 140 at each region 150a-150e is encoded into the distorted signal of the radiation. The radiation is subsequently received by the radiation detector 144, which converts the received radiation to a signal. The signals are then sent to the signal processing system 148 to produce information about the region 150a-150e measured.

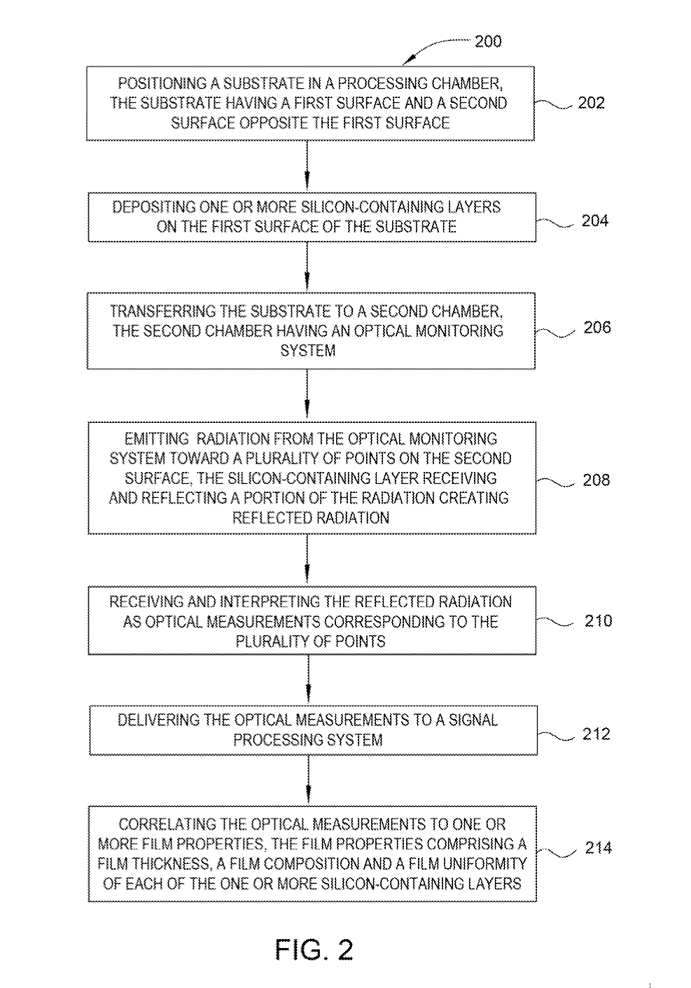

FIG. 2 is a block diagram of a method 200 for measuring film attributes, according to one embodiment. The method 200 includes positioning a substrate in a processing chamber, the substrate having a first surface and a second surface opposite the first surface; depositing one or more silicon-containing layers on the first surface of the substrate; transferring the substrate to a second chamber, the second chamber having an optical monitoring system; emitting radiation from the optical monitoring system toward a plurality of points on the second surface, the silicon-containing layer receiving and reflecting a portion of the radiation creating reflected radiation; receiving and interpreting the reflected radiation as optical measurements corresponding to the plurality of points; delivering the optical measurements to a signal processing system; and correlating the optical measurements to one or more film attributes, the film attributes comprising a film thickness, a film composition and a film uniformity of each of the one or more silicon-containing layers.

The method 200 begins by positioning a substrate in a processing chamber, at block 202. The substrate has a first surface and a second surface opposite the first surface. The substrate can be a standard substrate used in the production of semiconductor devices, such as in the production of displays. The substrate may be, among others, a thin sheet of metal, plastic, organic material, silicon, glass, quartz, or polymer materials. In one embodiment, the substrate is a glass substrate upon which a silicon-containing layer will be deposited. In other embodiments, the substrate may be doped or otherwise modified glass substrate. The substrate may have a surface area greater than about 1 square meter, such as greater than about 2 square meters. The present embodiments can be used for deposition of a silicon-containing layer (e.g., SiOₓ) on large-sized substrates having a plan surface area of about 15,600 cm², or greater, for example about a 90,000 cm² plan surface area.

One or more silicon-containing layers can then be deposited on the first surface of the substrate, at block 204. The process chamber may be configured to deposit a variety of materials on the substrate, including but not limited to dielectric materials (e.g., SiOₓ, SiOₓN_{y}, derivatives thereof or combinations thereof), semiconductive materials (e.g., Si and dopants thereof), barrier materials (e.g., SiNₓ, SiOₓN_{y} or derivatives thereof), or amorphous silicon or microcrystalline silicon thin film transistor (TFT) passivated by silicon-containing dielectric layer. Specific examples of dielectric materials and semiconductive materials that are formed or deposited by the process chamber onto the large area substrates may include, but is not limited to epitaxial silicon, polycrystalline silicon, amorphous silicon, microcrystalline silicon, silicon germanium, silicon dioxide, silicon oxynitride, silicon nitride, dopants thereof (e.g., B, P, or As), derivatives thereof or combinations thereof. The process chamber is also configured to receive gases such as argon, hydrogen, nitrogen, helium, or combinations thereof, for use as a purge gas or a carrier gas (e.g., Ar, H₂, N₂, He, derivatives thereof, or combinations thereof).

The substrate is then transferred to a second chamber, the second chamber having an optical monitoring system, at block 206. The substrate can be transferred using a transfer robot. The transfer robot can be positioned in the transfer chamber, described with reference to FIG. 1A. The substrate can be transferred from the processing chamber after deposition of the one or more silicon-containing layers on the substrate directly to the second chamber. In another embodiment, the substrate is transferred to a plurality of process chambers prior to being transferred to the second chamber. The second chamber may be a process chamber, a loadlock chamber, or a metrology chamber, described with reference to FIG. 1A.

The optical monitoring system includes a radiation source, a radiation detector, a substrate detector, a signal processing system or combinations thereof. In one embodiment, the optical monitoring system includes a reflectometer. The optical monitoring system is positioned at least at one entrance or exit of one of the chambers, such as the entrance or exit of the metrology chamber (if present), the entrance/exit of one or more of the process chambers, or the entrance or exit of the loadlock chamber. Further, a plurality of optical monitoring systems may be positioned at the entrance or exit for a plurality of chambers.

Radiation is then emitted from the optical monitoring system toward a plurality of points on the second surface, at block 208. The optical monitoring system can be activated to deliver radiation by any suitable manner. In one embodiment, the optical monitoring system uses a time based approach to determine when the substrate will be positioned over the radiation source of the optical monitoring system. In another embodiment, the optical monitoring system is activated by the substrate detector. The substrate detector may be a device for detecting motion in proximity to the optical monitoring system or in proximity to the entrance/exit, which can include a motion sensor.

Once the optical monitoring system is activated, a radiation can be emitted from a radiation source. The optical monitoring system can be positioned such that the radiation sources are directed to the surface opposite the silicon-containing layers. The silicon-containing layers then receive and reflect a portion of the radiation creating reflected radiation. The radiation is a wavelength which penetrates the substrate and is received, at least in part, by the silicon-containing layers. The reflected light is scattered according to the angle of incidence, wavelength and properties of the surface of the silicon-containing layers.

The reflected radiation is then received and interpreted as optical measurements corresponding to the plurality of points, at block 210. The angle of the refracted light, the intensity of the light, the speed at which the light is received by the detector and other parameters provide information related to film attributes at the point where the reflection occurred. Using a plurality of radiation sources, information related to film attributes can be collected across the substrate. Further, the information can be collected in line with the motion of the substrate, as it either enters or exits the chamber.

The optical measurements are then delivered to a signal processing system, at block 212. The signal processing system extracts one or more film attributes from the optical measurements, such as film thickness or film uniformity. The signal processing system can include controller(s), computer(s), and memory (or memories). The signal processing system is configured to receive and process the signals received from the radiation detector at each of the detectors of the optical monitoring systems.

The optical measurements are then correlated to one or more film attributes, at block 214. The film attributes can include a film thickness, a film composition and a film uniformity of one or more of the silicon-containing layers. Some properties can be derived from a single optical measurement, such as surface roughness. Other film attributes require multiple optical measurements, such as film uniformity.

The film attributes derived from the optical measurements can provide both properties of a single substrate as well as providing information regarding deposition on multiple substrates over a period of time. In one embodiment, the thickness and uniformity of the deposited layer of a number of substrates in a run may decrease as the layers are deposited. By monitoring the thickness and uniformity trend over time, alongside other information such as the clean count, preventative process tuning may be performed before low attribute uniformity falls outside of a predetermined process window.

In another embodiment, the method can include delivering a substrate through an opening in a processing chamber, the substrate having at least one deposited layer disposed on a surface of the substrate, the opening in the processing chamber having an optical monitoring system positioned in connection therewith. The optical monitoring system can then be activated such that the optical monitoring system performs a plurality of optical measurements of the at least one deposited layer, the optical measurements are performed continuously along the respective region of the substrate. The optical measurements can be delivered to a signal processing system. The optical measurements can then be correlated to one or more film attributes.

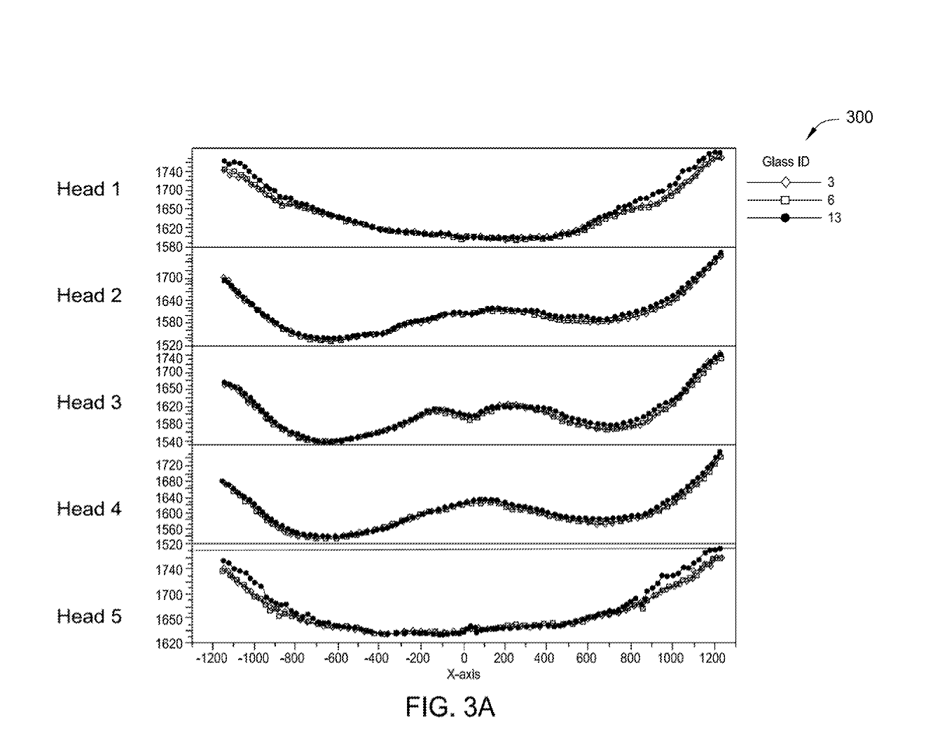

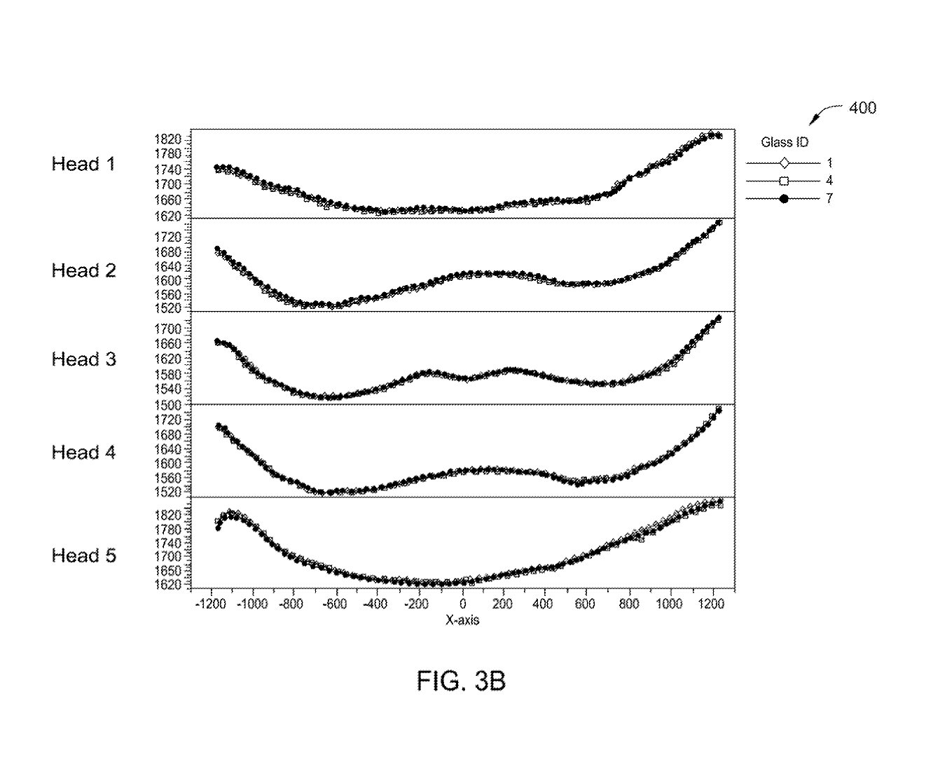

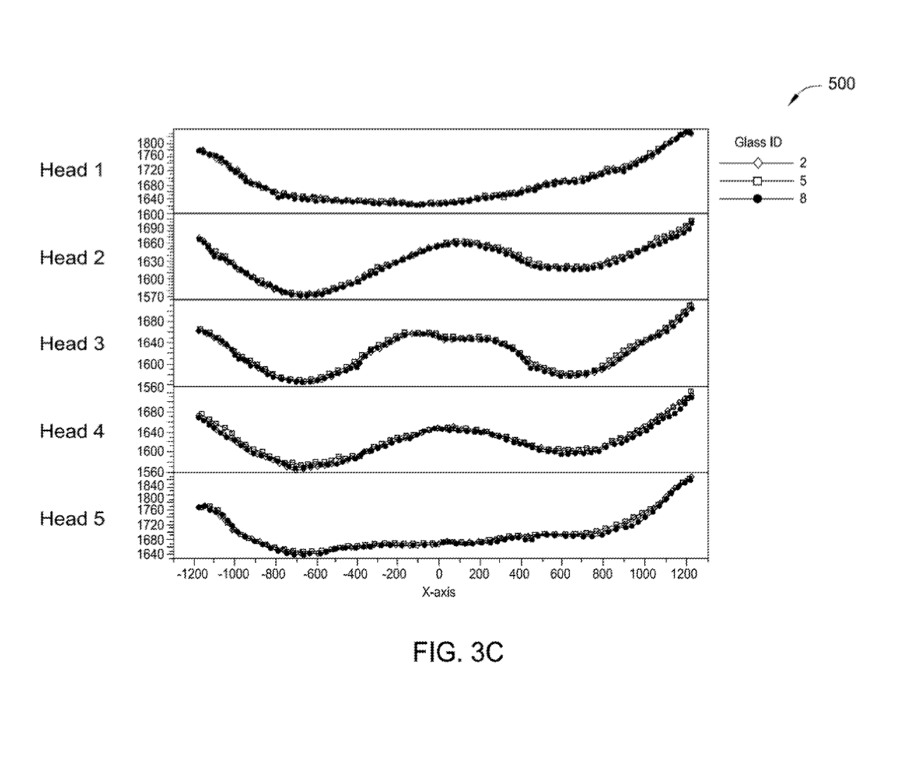

FIGS. 3A-3C depict thickness maps of a plurality of silicon-containing layers, measured according to embodiments described herein. A total of nine (9) substrates were optically measured to determine the thickness of the silicon-containing layer, using methods and devices described herein. The optical monitoring system consisted five optical heads, each comprising a radiation source, a photo diode, a substrate detector and signal processing system. The optical monitoring system was mounted at the loadlock exit of the cluster tool, as shown in FIG. 1A. The substrates were moving at a speed of 0.2 m/s to 2.0 m/s while the measurements were obtained.

FIG. 3A depicts a graph 300 of the thickness maps of three substrates, indicated as Glass Identification (ID) numbers. 3, 6 and 13. For these substrates, the silicon containing layer was silicon nitride. Glass ID numbers 3, 6 and 13 went through the same processing chamber used for deposition of the silicon-containing layer. The thickness of the silicon-containing layer was measured in angstroms (Å) across the length of the substrate. The measurements were taken using five (5) heads for each of the substrates and the data points were graphed as shown.

The measured thickness of the Glass ID numbers 3, 6 and 13 are approximately the same at each of the heads, with the primary variance occurring at the edges of the substrate. The thickness at Head 1 of Glass ID numbers 3, 6 and 13 varied from about 1600 Å in the middle to about 1800 Å at the edges. The thickness at Head 2 of Glass ID numbers 3, 6 and 13 varied from about 1520 Å in the first bow (at about −700 on the X-axis) to about 1700 Å at the edges. The second bow (at about 700 on the X-axis) was slightly thicker, being approximately 1580 Å thick. The thickness at Head 3 of Glass ID numbers 3, 6 and 13 varied from about 1540 Å in the first bow (at about −700 on the X-axis) to about 1740 Å at the edges. The second bow (at about 700 on the X-axis) was slightly thicker, being approximately 1580 Å thick. The thickness at Head 4 of Glass ID numbers 3, 6 and 13 varied from about 1520 Å in the first bow (at about −700 on the X-axis) to about 1730 Å at the edges. The second bow (at about 700 on the X-axis) was slightly thicker, being approximately 1580 Å thick. The thickness at Head 5 of Glass ID numbers 3, 6 and 13 varied from about 1630 Å in the middle to about 1760 Å at the edges.

FIG. 3B depicts a graph 400 of the thickness maps of three substrates, indicated as Glass ID numbers 1, 4 and 7. For these substrates, the silicon containing layer was silicon nitride. Glass ID numbers 1, 4 and 7 went through the same processing chamber used for deposition of the silicon-containing layer. The thickness of the silicon-containing layer was measured in angstroms (Å) across the length of the substrate. The measurements were taken using five (5) heads for each of the substrates and the data points were graphed as shown.

The measured thickness of the Glass ID numbers 1, 4 and 7 are approximately the same at each of the heads, with the primary variance occurring at the edges of the substrate, if at all. The thickness at Head 1 of Glass ID numbers 1, 4 and 7 varied from about 1630 Å in the middle to about 1820 Å at the edges. The thickness at Head 2 of Glass ID numbers 1, 4 and 7 varied from about 1520 Å in the first bow (at about −700 on the X-axis) to about 1720 Å at the edges. The second bow (at about 700 on the X-axis) was slightly thicker, being approximately 1600 Å thick. The thickness at Head 3 of Glass ID numbers 1, 4 and 7 varied from about 1510 Å in the first bow (at about −700 on the X-axis) to about 1720 Å at the edges. The second bow (at about 700 on the X-axis) was slightly thicker, being approximately 1550 Å thick. The thickness at Head 4 of Glass ID numbers 1, 4 and 7 varied from about 1520 Å in the first bow (at about −700 on the X-axis) to about 1730 Å at the edges. The second bow (at about 700 on the X-axis) was slightly thicker, being approximately 1550 Å thick. The thickness at Head 5 of Glass ID numbers 1, 4 and 7 varied from about 1630 Å in the middle to about 1820 Å at the edges. The first edge shows an abrupt change in thickness on each of the substrates from about 1780 Å to about 1800 Å at between about −1200 and about −1100 on the X-axis.

FIG. 3C depicts a graph 500 of the thickness maps of three substrates, indicated as Glass ID numbers 2, 5 and 8. For these substrates, the silicon containing layer was silicon nitride. Glass ID numbers 2, 5 and 8 went through the same processing chamber used for deposition of the silicon-containing layer. The thickness of the silicon-containing layer was measured in angstroms (Å) across the length of the substrate. The measurements were taken using five (5) heads for each of the substrates and the data points were graphed as shown.

The measured thickness of the Glass ID numbers 2, 5 and 8 are approximately the same at each of the heads, with the primary variance occurring at the edges of the substrate, if at all. The thickness at Head 1 of Glass ID numbers 2, 5 and 8 varied from about 1640 Å in the middle to about 1820 Å at the edges. The thickness at Head 2 of Glass ID numbers 2, 5 and 8 varied from about 1580 Å in the first bow (at about −700 on the X-axis) to about 1700 Å at the edges. The second bow (at about 700 on the X-axis) was slightly thicker, being approximately 1630 Å thick. The thickness at Head 3 of Glass ID numbers 2, 5 and 8 varied from about 1560 Å in the first bow (at about −700 on the X-axis) to about 1700 Å at the edges. The second bow (at about 700 on the X-axis) was slightly thicker, being about 1600 Å thick. The thickness at Head 4 of Glass ID numbers 2, 5 and 8 varied from about 1560 Å in the first bow (at about −700 on the X-axis) to about 1700 Å at the edges. The second bow (at about 700 on the X-axis) was slightly thicker, being approximately 1600 Å thick. The thickness at Head 5 of Glass ID numbers 2, 5 and 8 varied from about 1630 Å at about −700 on the X-axis to about 1820 Å at the edges. The first edge shows an abrupt change in thickness on each of the substrates from about 1760 Å to about 1780 Å at between about −1200 and about −1100 on the X-axis.

Shown here, the thickness profile of a substrate can be measured using an optical monitoring system. The 5 heads provide information about the substrates, while the substrates are moving at standard operating speeds. The optical measurements provide time correlated information about the measured region which can be associated with other time-correlated information to create a map of the thickness and uniformity across the substrate. Based on these maps, unique thickness profile signatures from different chambers were found. These chambers were running the same recipe, which provides information not only about process drifts, but also equipment status change.

The embodiments of the invention described herein generally relate to the measurement of silicon-containing layers. An optical monitoring system is positioned at the entrance or exit of a chamber. As the substrate cross the threshold of the entrance or exit of the chamber, the optical monitoring system is activated to direct radiation toward the back side of the substrate. The substrate is permeable to the radiation and the silicon-containing layer reflects a portion of the radiation back to the detector. Based on parameters of the reflected radiation, the thickness, uniformity and other film attributes can be determined.

While the foregoing is directed to embodiments of the present invention, other and further embodiments of the invention may be devised without departing from the basic scope thereof, and the scope thereof is determined by the claims that follow.

1. A processing device comprising:
a transfer chamber;
one or more processing chambers, the processing chambers each comprising a processing entrance proximate the transfer chamber;
a loadlock chamber comprising a loadlock entrance and a loadlock exit; and
an optical monitoring system positioned outside of and under an opening, the opening selected from the processing entrance, the loadlock entrance or the loadlock exit, the optical monitoring comprising a plurality of optical devices positioned horizontally under the opening, the optical monitoring system comprising a radiation source, a radiation detector, a substrate detector, and a signal processing system, the optical monitoring system configured to deliver radiation at a substrate position.

2. The processing device of claim 1, wherein the optical device comprises a reflectometer.

3. The processing device of claim 1, wherein the optical monitoring system is positioned at the loadlock exit.

4. The processing device of claim 1, wherein the optical monitoring system comprises five optical devices.

5. The processing device of claim 1, wherein the optical devices are activated by substrate motion as detected by the substrate detector.

6. The processing device of claim 5, wherein the optical monitoring system is positioned such that the radiation source faces upward.

7. The processing device of claim 1, wherein at least one of the processing chambers is a CVD processing chamber.

8. A method of measuring film attributes, comprising:
delivering a substrate through an opening in a processing chamber, the substrate having at least one deposited layer disposed on a surface of the substrate, the opening in the processing chamber having an optical monitoring system positioned in connection therewith;
activating the optical monitoring system such that the optical monitoring system performs a plurality of optical measurements of the at least one deposited layer, the optical measurements being continuous along the respective region of the substrate;
delivering the optical measurements to a signal processing system; and
correlating the optical measurements to one or more film attributes.

9. The method of claim 8, wherein the deposited layer is a silicon-containing layer.

10. The method of claim 8, wherein the plurality of optical measurements are performed on a plurality of regions.

11. The method of claim 8, wherein activating the monitoring system comprises:
passing a substrate in the detectable range of a substrate detector, wherein the substrate detector detects the presence of the substrate; and
sending a signal from the substrate detector to a radiation source on the optical monitoring system in response to detecting a substrate.

12. The method of claim 8, wherein the plurality of optical measurements are taken simultaneously.

13. The method of claim 8, wherein the one or more deposited layers is a plurality of deposited layers.

14. The method of claim 13, wherein correlating the optical measurements includes differentiating between the film attributes of the plurality of deposited layers.

15. The method of claim 8, wherein the optical monitoring system produces a wavelength of radiation, and wherein the substrate is translucent or transparent to the wavelength of radiation.

16. A method of measuring film attributes, comprising:
positioning a substrate in a processing chamber, the substrate having a first surface and a second surface opposite the first surface;
depositing one or more silicon-containing layers on the first surface of the substrate;
transferring the substrate to a second chamber, the second chamber having an optical monitoring system;
emitting radiation from the optical monitoring system toward a plurality of points on the second surface, the silicon-containing layer receiving and reflecting a portion of the radiation creating reflected radiation;
receiving and interpreting the reflected radiation as optical measurements corresponding to the plurality of points;
delivering the optical measurements to a signal processing system; and
correlating the optical measurements to one or more film attributes, the film attributes comprising a film thickness, a film composition and a film uniformity of each of the one or more silicon-containing layers.

17. The method of claim 16, wherein the second chamber is a loadlock chamber.

18. The method of claim 16, wherein the optical monitoring system is positioned facing the second surface of the substrate.

19. The method of claim 16, wherein the optical measurements are taken at a plurality of points in a plurality of regions, the regions corresponding to a fixed measured 2 dimensional space of the one or more silicon containing layers.

20. The method of claim 19, wherein the signal processing system interprets a third dimension of each of the plurality of regions using the optical measurement
